(19) United States
(12) Patent Application Publication
(10) Pub. No.: US 2007/0243722 A1
(43) Pub. Date: Oct. 18, 2007

(54) SILICON CARBIDE SEMICONDUCTOR DEVICE AND MANUFACTURING METHOD THEREOF

(75) Inventors: Shun-ichi NAKAMURA, Matsumoto (JP); Yoshiyuki YONEZAWA, Matsumoto (JP)

Correspondence Address: ROSSI, KIMMS & McDOWELL LLP., P.O. BOX 826, ASHBURN, VA, 20146-0826, US

(73) Assignee: FUJI ELECTRIC HOLDINGS CO., LTD, Kawasaki-ku (JP)

(21) Appl. No.: 11/736,662

(22) Filed: Apr. 18, 2007

(30) Foreign Application Priority Data
Apr. 18, 2006 (JP) JP 2006-114793

(51) Int. Cl. H01L 21/31

(52) U.S. Cl. 438/787

(57) ABSTRACT

A method of manufacturing a device on a silicon carbide substrate is disclosed. The device includes an oxide layer which has silicon oxide as a main component on the silicon carbide semiconductor substrate. The method includes depositing and oxide layer on a surface of the silicon carbide semiconductor substrate; raising a temperature of the oxide layer in a non-oxidizing atmosphere to a temperature bringing the oxide layer into a liquefied state; and then rapidly cooling the oxide layer down to a temperature equal to or less than 1140° C. to form the oxide layer including silicon oxide as a main component. The silicon carbide semiconductor device has improved channel mobility to lower on-resistance by decreasing an interface state density at an interface between the oxide insulator film that has silicon oxide as its main component and the silicon carbide semiconductor substrate.

### CROSS REFERENCE TO RELATED APPLICATIONS

This application claims priority from application Serial No. JP 2006-114793, filed on Apr. 18, 2006, the contents of which are incorporated herein in their entirety.

### BACKGROUND OF THE INVENTION

A. Field of the Invention

The present invention relates to a silicon carbide semiconductor device formed as a device such as a MOSFET (insulated gate metal-oxide-semiconductor field effect transistor), an IGBT (insulated gate bipolar transistor), a bipolar transistor or a diode by using a silicon carbide semiconductor substrate, and a manufacturing method of the device.

B. Description of the Related Art

It is reported that a high breakdown voltage power device fabricated by using a silicon carbide (SiC) semiconductor substrate has a possibility of considerably lowering on-resistance of the device. In recent years, low on-resistance less than 10 mΩcm² has been obtained in a MOSFET of SiC of 1.2 to 1.7 kV class. This is lower than the on-resistance of an IGBT of silicon (Si) of the same breakdown voltage class. At present, although on-resistance can be lowered, the extent of the lowering is insufficient, and there exists a desire for even further lowering. Further cost reduction and on-resistance lowering, carried out hereafter in comparison with devices such as an IGBT of Si and a MOSFET of Si, may lead to the expectation that most IGBTs of Si as the parts of inverters may be substituted by MOSFETs of SiC.

The reason that the on-resistance of a device can be considerably reduced by using a SiC semiconductor substrate is as follows. Namely, high insulation breakdown electric field strength of a SiC semiconductor substrate allows a high-resistance drift layer to be thin or the amount of doping in a drift layer can be increased to realize the same high breakdown voltage. This can lower the resistance of the drift layer of the SiC semiconductor substrate by two figures or more compared with that of a Si semiconductor substrate (hereinafter sometimes abbreviated to be simply referred to as Si).

However, in a MOS device using a SiC substrate, of resistance components constituting the on-resistance thereof, the resistance component of a drift layer has a ratio that becomes relatively small for the reason explained previously. Therefore, the ratios of the other components, the resistance component of a MOS channel region controlling the switching of a current (referred to as channel resistance), the resistance component of a high impurity concentration semiconductor substrate and further, even the component of contact resistance with an electrode, conversely have a magnitude that cannot be negligible. In particular, because the state at a SiO₂/SiC interface (where the expression “a/b interface” represents an interface between a and b) is not as good as the state at a SiO₂/Si interface at present, the MOS channel mobility at the SiO₂/SiC interface is liable to be smaller by an order of a magnitude than the MOS channel mobility at the SiO₂/Si interface (where the notation with SiO₂ represents any one of a SiO₂ layer, a SiO₂ film and a SiO₂ material). As a result, the channel resistance of the SiC semiconductor substrate ordinarily is larger than the channel resistance of a Si semiconductor substrate, thereby causing the ratio of the channel resistance to the whole on-resistance to further increase remarkably. Actually, in many of the SiC MOSFETs reported up to now, fractions of 30 to 50% of on-resistance are occupied by channel resistance components. Therefore, in an SiC MOSFET lowering of the channel resistance becomes a more important subject in reducing on-resistance than in a Si MOSFET.

The cause of making the MOS channel mobility at a SiO₂/SiC interface smaller than that at a SiO₂/Si interface is explained as being due to the presence of a high density interface state at the SiO₂/SiC interface. As the cause of the presence of the high density interface state, the presence of suboxides or carbon clusters around the SiO₂/SiC interface is suspected. A suboxide is a compound in which SiC is not completely oxidized with bonds such as Si—O bonds, C—O bonds and Si—C bonds being present as mixtures. A carbon cluster is a compound in a state with fine particles of carbon having graphite-like bonds being scattered in SiO₂. Silicon carbide, like Si, is able to form SiO₂ by thermal oxidation. However, unlike Si, C is present in SiC. Thus, suboxides or carbon clusters are produced.

In recent years, an attempt has been carried out in which, instead of forming SiO₂ by thermal oxidation, CVD-SiO₂ (SiO₂ formed by Chemical Vapor Deposition) is formed by deposition and subjected to heat treatment. Nevertheless, for a CVD-SiO₂ formed by deposition to obtain favorable MOS interface characteristics, heat treatment in an oxidizing atmosphere is still necessary. However, to carry out the heat treatment in the oxidizing atmosphere is also to gradually oxidize the SiC from the interface with the SiO₂ deposited thereon. The film thickness of the SiO₂ at the interface increased by the heat treatment in the oxidizing atmosphere also largely affects MOS channel mobility. It is reported that the SiO₂ newly formed at the interface by the heat treatment in the oxidizing atmosphere reduces MOS channel mobility when the film thickness is too thin or too thick (see, Kawano et al., Extended Abstracts (The 52th Spring Meeting, 2005) 1a-YK-9; The Japan Society of Applied Physics and Related Societies). The reason is not disclosed in the document, but is considered to be as follows. Unless heat treatment is carried out in an oxidizing atmosphere, the bond between SiC and CVD-SiO₂, being originally weak, produces an interface state due to the weak bond to cause MOS channel mobility to decrease. Moreover, excessive thermal oxidation of SiC causes suboxides or carbon clusters at a MOS interface to increase as in the case of forming a thermal oxidation film. This results in an increase in an interface state density to decrease MOS channel mobility.

As to the interface between SiC and CVD-SiO₂, it can be assumed that only carbon clusters can be removed by carrying out heat treatment in a non-oxidizing atmosphere, which moves the carbon clusters for being removed. However, it is additionally reported that carbon atoms are actually almost impossible to move in SiO₂ in a non-oxidizing atmosphere even by heating, and that oxidation of carbon in an oxidizing atmosphere is the necessary condition for moving carbon atoms in SiO₂ (see, O. H. Krafcsik et al.: Materials Science Forum, vols. 353-356 (2001) pp. 659-662). In this case, however, the oxidizing atmosphere causes thermal oxidation on the surface of the SiC to simultaneously occur, which produces SiO₂ with carbon atoms newly taken therein. As a result, complete removal of carbon is impossible.

As to the suboxide, it cannot be removed naturally without redox reaction. Thus, using a current method of forming a SiO₂/Si interface, it is impossible simultaneously to achieve the formation of a proper bond between SiO₂ and SiC and the removal of suboxides or carbon clusters produced owing to C in SiC. Thus, it is considered that an interface state density is likely increase. For these reasons, it was previously said that the improvement of the MOS channel mobility at the SiO₂/SiC was difficult. This results in the present status in which the difficulty in lowering channel resistance, the largest component of the whole on-resistance, also makes it difficult to further lower on-resistance. To breakdown the present status for further lowering of on-resistance is a large subject in providing a high breakdown voltage power semiconductor device using a SiC semiconductor substrate.

The invention was made in view of the foregoing. An object of the invention is to provide a silicon carbide semiconductor device, in which production of suboxides and carbon clusters is inhibited at an interface between an oxide insulator film, including silicon oxide as a main component, and a silicon carbide semiconductor substrate, decreasing an interface state density to improve channel mobility to allow on-resistance to be lowered, and a manufacturing method of the device.

The present invention is directed to overcoming or at least reducing the effects of one or more of the problems set forth above.

### SUMMARY OF THE INVENTION

According to a first aspect of the invention, the object of the invention can be achieved by providing a method of manufacturing a silicon carbide semiconductor device including a process of forming an oxide layer, which includes silicon oxide as a main component, on a silicon carbide semiconductor substrate, in which the process includes the steps of:

forming a layer of silicon oxide on a surface of the silicon carbide semiconductor substrate;

raising thereafter a temperature of the layer of silicon oxide in a non-oxidizing atmosphere to a temperature bringing the silicon oxide into a liquefied state containing no crystal; and

rapidly cooling thereafter the layer of silicon oxide down to a temperature equal to or less than a slow cooling temperature to form the oxide layer including silicon oxide as a main component.

According to a second aspect of the invention, the method of manufacturing a silicon carbide semiconductor device according to the first aspect is preferably provided in which the temperature bringing the silicon oxide into a liquefied state containing no crystal is 1730° C. or more and the slow cooling temperature is a temperature at which no crystal of SiO₂ is substantially produced in SiO₂ in an amorphous state.

According to a third aspect of the invention, the method of manufacturing a silicon carbide semiconductor device according to the second aspect of the invention is more preferably provided in which the slow cooling temperature is 1140° C.

According to a fourth aspect of the invention, the object of the invention can be achieved by providing a method of manufacturing a silicon carbide semiconductor device including a process of forming an oxide layer, which includes silicon oxide as a main component, on a silicon carbide semiconductor substrate, in which the process includes the steps of:

forming a layer of silicon oxide on a surface of the silicon carbide semiconductor substrate;

heating thereafter the layer of silicon oxide to a temperature between 1250° C. and 1450° C. under a supply of gaseous silicon in a non-oxidizing atmosphere; and

rapidly cooling the layer of silicon oxide down to a temperature equal to or less than 1140° C. to form the oxide layer including silicon oxide as a main component.

According to a fifth aspect of the invention, the method of manufacturing a silicon carbide semiconductor device according to the fourth aspect is preferably provided in which the gaseous silicon is mainly produced from hydrogenated silicon.

According to a sixth aspect of the invention, the method of manufacturing a silicon carbide semiconductor device according to the fifth aspect is a method in which the hydrogenated silicon is silane.

According to a seventh aspect of the invention, a silicon carbide semiconductor device is appropriately made to have a structure provided with a metal electrode on a surface of a silicon carbide semiconductor substrate with the oxide layer according to any one of the first to sixth aspects held between which layer includes silicon oxide as a main component.

According to an eighth aspect of the invention, the silicon carbide semiconductor device according to the seventh aspect desirably is provided in which all of metal electrodes and a MOS gate structure of a MOSFET are provided on one of principal surfaces of the silicon carbide semiconductor substrate.

According to a ninth aspect of the invention, the silicon carbide semiconductor device according to the seventh aspect also can be provided in which the metal electrode are provided on each of the principal surfaces so that a current path is provided from the one of the principal surfaces to the other principal surface of the silicon carbide semiconductor substrate and the MOS gate structure is provided on either one of the principal surfaces.

According to a tenth aspect of the invention, the silicon carbide semiconductor device according to the eighth or ninth aspect is more desirably provided in which the MOS gate structure is a trench MOS gate structure.

According to an eleventh aspect of the invention, a silicon carbide semiconductor device is appropriately provided in which a trench MOS gate structure is provided on one of principal surfaces of a silicon carbide semiconductor substrate, and an oxide layer in a trench of the trench MOS gate structure is the oxide layer according to any one of the first to the third aspects which layer includes the silicon oxide as a main component.

According to the concept of the invention, a method of manufacturing a semiconductor includes process steps of forming an oxide layer, which includes SiO₂ as a main component, on a SiC semiconductor substrate in a non-oxidizing atmosphere, and making carbon impurities in the oxide layer (hereinafter an oxide layer including SiO₂ as a main component is referred to simply as an oxide layer) spent in epitaxial growth of SiC on the surface of the SiC semiconductor substrate. For a specific manufacturing method including the process step of making the carbon impurities spent in epitaxial growth of SiC, there are two methods. A first method is a method including the step of raising the temperature of the oxide layer on the surface of the SiC semiconductor substrate to bring the oxide layer into a liquefied state including no SiO₂ crystal before the oxide layer is cooled rapidly down to 1140° C. to solidify it. A second method is a method including the step of heating the oxide layer in an atmosphere of a silicon supplying gas such as Si, an oxide of Si (limited to an oxide that oxidizes no SiC), hydrogenated Si or a mixture of these materials, up to a temperature range between 1250° C., at which the diffusion rate of Si in SiO₂ becomes substantially effective, and 1450° C., at which the vapor pressure of SiO₂ becomes high, and then rapidly cooling the oxide layer down to 1140° C. or less.

In general, the SiO₂ formed on the semiconductor substrate is in an amorphous state. Thus, for the liquefied state in the first method, the solid phase and the liquid phase of the formed SiO₂ cannot be strictly distinguished. Therefore, the liquefied state of the SiO₂ is defined as being a state in which the temperature of the SiC semiconductor substrate becomes higher than the upper limit of the glass transition temperature of an oxide layer formed on the substrate (including a state in which the temperature of the SiC semiconductor substrate is equal to or greater than the melting point of a silicon oxide crystal). However, since crystals of SiO₂ are liable to be formed at a temperature equal to or greater than the glass transition temperature of the oxide layer, in the invention the liquefied state is referred to as a state at temperatures above the melting point of a SiO₂ crystal. This melting point is 1730° C. and thus, the liquefied state of the oxide layer is referred to as a state above 1730° C. in the invention. A solidified state in the invention is a state in which the temperature of the oxide layer on the SiC semiconductor substrate is lower than or equal to the glass transition temperature from the temperature of a liquefied state. With the oxide layer in the liquefied state, at the interface of the SiC semiconductor substrate in contact with the oxide, carbon impurities in the oxide are removed by the following reaction:

SiO₂+3C→SiC+2CO.

In the chemical equation, the SiC on the right side of the arrow formed by the reaction is spent in epitaxial growth on the SiC surface in contact with the oxide with the formed CO diffusing in the oxide to dissipate into a vapor phase. Suboxides present at the oxide/SiC interface can be considered to be treated by separating the suboxides into components such as SiC, SiO₂, C and CO depending on the composition thereof. Of the components, excessive C is removed by the above reaction.

Only by heat treatment carried out at such a low temperature that no oxide enters a liquefied state, carbon impurities in the oxide and suboxides at the oxide/SiC interface cannot be removed (except the second method). In respect to energy of formation, the reaction of the chemical equation seems to progress at temperatures that are at least above 1100° C. to 1200° C. (amorphous phase included in the oxide provides insufficient thermodynamics data to make the temperature indefinite). However, below the glass transition temperature, the network structure of SiO₂ is frozen, which might prevent actual progress of the reaction.

The oxide layer may be formed by any method prior to converting it to the liquefied state. It may be formed by thermal oxidation as before, or by deposition methods such as thermal CVD and plasma CVD. Moreover, the oxide layer may be formed in layers by a plurality of the methods. Furthermore, the oxide layer is not necessarily formed in layers but may be formed like a pile of fine particles of SiO₂ because the pile becomes dense by heat treatment carried out after the particles were piled up. However, when the oxide layer formed by the method according to the invention is used as a gate insulator film of a MOSFET, it is necessary to carry out control so that the film with a thickness of the order of 40 to 100 nm is formed with good repeatability. Thus, it is preferable to take a method of forming SiO₂ that can accurately control the number of moles (not the film thickness) of the oxide with good repeatability like the thermal oxidation method, for example.

It is well known that a temperature must be elevated to 1730° C. or above to realize an ideal liquefied state of pure SiO₂. This is because some SiO₂ crystals that can be formed under normal pressure are present in a crystal form with the melting point thereof reaching as high as 1730° C. (in a form of high temperature cristobalite). It is known that SiO₂, kept at an intermediate temperature lower than the melting point of SiO₂ crystal for a long time, causes microcrystals of SiO₂ to deposit in softened amorphous SiO₂. A reaction tube of high-purity silica glass (SiO₂ as composition) being used at 1150° C. for thermal oxidation of SiC gradually becomes whitish with each of the deposited microcrystals grown to have a length or a diameter larger than the wavelength of light. When cooling SiO₂ from a state heated at 1730° C. or above, the SiO₂ must be rapidly cooled so as not to be kept for a long time in a temperature range in which microcrystals are liable to deposit. Although the SiO₂ is rapidly cooled, SiO₂ used in a semiconductor element is very thin, so that the thermal strain inside the SiO₂ due to rapid cooling does not cause much of a problem. In respect to strain, the strain due to the difference in thermal expansion coefficient between the SiO₂ and a SiC semiconductor substrate rather causes a problem. Moreover, high durability against insulation breakdown is required for SiO₂, so that deposition of microcrystals in SiO₂ must be inhibited to the least possible extent. This is because deposition of microcrystals causes the SiO₂ to be easily electrically broken down by electric field concentration caused by difference in permittivity between the SiO₂ and an amorphous matrix region of the SiO₂ and, with some crystal forms of the microcrystals, by stress caused by strain due to piezoelectric effect. From such a viewpoint, it is preferable that the SiO₂ is first rapidly cooled down to a slow cooling temperature thereof (1140° C. for silica glass) and thereafter slowly cooled while relaxing stress due to strain in a viscous flow state. When the cooling cannot be stopped at an intermediate temperature for some reason, heat treatment must be carried out again later at a temperature of the order of 1070 to 1140° C. Such heat treatment must, of course, be carried out in a non-oxidizing atmosphere.

The vapor pressure of SiO₂ is 10 Torr at 1732° C. It is said that SiO₂ has a vapor pressure to some extent even before being brought to a liquefied state. Therefore, in a simple inert gas flow, a SiO₂ formed beforehand is lost by evaporation. To avoid this, an evaporation source of SiO₂ is preferably disposed on the upstream side of the gas flow with the temperature thereof kept the same as that of the formed SiO₂ so that SiO₂ with saturated vapor pressure is present in the vapor phase in a section of the SiO₂ on the SiC semiconductor substrate. Under normal pressure, the SiO₂ semiconductor substrate itself is neither molten nor sublimed nor decomposed with diffusion coefficients of impurity atoms (N, P, Al etc.) except B (boron) atoms that are doped for controlling conductivity types being also small to an actually negligible extent even at 1800° C. Hence, heating SiC up to the temperature is not a problem. However, in carrying out heat treatment at such a temperature, there is a limitation on the heat treatment system. For example, heat treatment of a SiO₂ is normally carried out in a reaction tube of high-purity silica glass. In the method according to the invention, however, heat treatment of the SiO₂ must be carried out by heating the SiO₂ up to a temperature above the softening point of silica glass (to be on the order of 1650° C.). This makes it impossible to use a reaction tube of silica glass. Alumina is normally used as a material resistant to temperatures higher than the above temperature. However, alumina includes many metallic impurities which are taken in heat-treated SiO₂. In particular, metallic impurity atoms such as Na atoms which become mobile ions in SiO₂ adversely affect characteristics of a semiconductor device. Thus, as is well known, application of alumina to a semiconductor manufacturing system causes such a serious problem that it is strictly avoided in a current Si process. In an annealing process carried out after ion implantation into the SiC substrate, like the method according to the invention, heat treatment at 1700 to 1800° C. sometimes becomes necessary. A popular current heat treatment system currently used is a system in which a susceptor of graphite base is held on a thermal insulation in a quartz tube to be subjected to induction heating. Such a system has a problem of causing a slow cooling speed because the susceptor has a large heat capacity and is held on thermal insulation. For an annealing process after ion implantation, an electron bombardment annealing system is also developed (M. Shibagaki et al.,: Materials Science Forum vols. 483-485 (2005) pp. 609-612). In the system introduced in the document, the time required for cooling from 1730° C. to 1000° C. is only several minutes. Although such a system is not generally used at present, it can be said that the system is preferable in effectively carrying out the invention.

Addition of phosphorus or boron, for example, to SiO₂ is also possible for lowering heat treatment temperature, following the example of using so-called PSG (Phospho Silicate Glass) or BPSG (Boro Phospho Silicate Glass). However, unlike the case of using PSG or BPSG, phosphorus or boron volatilizes from a relatively low temperature. Although the melting point of P₂O₅ is on the order of 560 to 580° C., the sublimation of P₂O₅ begins from on the order of 350° C. B₂O₃ has a melting point of the order of 450 to 480° C. and a boiling point of the order of 1500° C. Therefore, it is difficult to keep the composition of added phosphorus or boron. As in the case of heat treatment of pure SiO₂, it is necessary to implement techniques such as those of disposing an evaporation source with a desired composition on the upstream side of the gas flow and carrying out rapid heating and cooling. Although there are difficulties when phosphorus or boron is added to SiO₂, the addition does lower the value of the softening point of SiO₂ to bring the thermal expansion coefficient closer to the value of SiC. This provides the advantage of reducing the strain in a formed oxide insulator film.

In a specific way of the second method that makes carbon impurities in oxide spent in epitaxial growth of SiC on the surface of a SiC semiconductor substrate in a non-oxidizing atmosphere, the oxide is heated in an atmosphere of Si, oxide of Si (limited to oxide oxidizing no SiC), hydrogenated Si or a mixture of these materials. With such heating, carbon impurities in the oxide that are present around an oxide/SiC interface (an interface state is formed only by carbon impurities around the interface) are removed by being spent in epitaxial growth on the SiC semiconductor substrate together with Si reaching the interface by diffusion in the oxide. As in the first method, suboxides at the oxide/SiC interface can be treated by separating the suboxides into components thereof, such as SiC, SiO₂, C and CO depending on the components, of which excessive C, like the carbon impurities in the oxide, is removed by being spent in epitaxial growth on the SiC semiconductor substrate together with Si reaching the interface by diffusion in the oxide.

According to the invention, an oxide is formed in an atmosphere oxidizing no SiC. This allows carbon impurities and suboxides to be removed without reproducing carbon impurities in the oxide and without reproducing suboxides at the oxide/SiC interface. By the first method according to the invention, by SiO₂ being in a liquefied state including no crystalline materials, the reaction expressed by the above chemical equation is activated to allow effective removal of carbon impurities and suboxides.

By the second method according to the invention, Si atoms diffusing in the oxide force carbon impurities or suboxides to be spent. Furthermore, as opposed to the first method, the second method has an advantage of necessitating no such abnormally high temperature as to make SiO₂ in a liquefied state including no crystalline materials. Furthermore, the first method also has the effect as explained below when applied to the case of forming an oxide layer, including SiO₂ as a main component, so as to fill an engraved section on the principal surface of a SiC substrate or a part thereof. Namely, even though the oxide layer first fills the engraved section on the SiC substrate with some clearance left between, when the oxide layer is then liquefied before being solidified it can finally fill the engraved section without clearance. This can simplify production process of the SiO₂.

### BRIEF DESCRIPTION OF THE DRAWINGS

The foregoing advantages and features of the invention will become apparent upon reference to the following detailed description and the accompanying drawings, of which:

FIG. 1 is a cross sectional view showing a principal part of a lateral MOSFET according to Example 5 of the invention;

FIG. 2 is a cross sectional view showing a principal part of a vertical MOSFET according to Example 6 of the invention; and

FIG. 3 is a cross sectional view showing a principal part of a trench MOSFET according to Example 7 of the invention.

### DETAILED DESCRIPTION OF SPECIFIC EMBODIMENTS

### Example 1

In Example 1, the manufacturing method of an n-type SiC-MOS capacitor according to the invention will be explained. Change in conduction type allows a p-type SiC-MOS capacitor to be manufactured in the same way as that in Example 1 explained below. Furthermore, by forming parts such as a drain, a source electrode and a gate electrode with a publicly known method, a device such as an n-channel or a p-channel MOSFET can be easily manufactured.

First, an alumina boat is prepared. Upstream from the boat, a SiC dummy substrate (which is not necessarily a single crystal) is disposed on which a 5 mm thick SiO₂ has been deposited. The width of the dummy substrate sample to a gas flow is taken as at least wider than the width (50.8 mm in diameter) of a later described SiC substrate sample to be originally processed, 55 mm square, for example. Downstream from the boat, the SiC substrate sample is disposed for manufacturing the n-type SiC-MOS capacitor according to the invention.

In Example 1, for SiC substrate samples for forming n-type SiC-MOS capacitors according to the invention, an n-type 4H—SiC (0001)_{Si}, (000 1̅)_{C} plane 8° off substrate (0.01 to 0.02 Ωcm in resistivity) with a 50.8 mm diameter and an n-type 4H—SiC (11 2̅0) on-axis plane substrate with 15 mm square are prepared. On each of the thus prepared substrate samples, an n-type SiC epitaxial layer (donor density of 1×10¹⁶ cm⁻³) is provided to a thickness of the order of 2 μm, on which SiO₂ is further formed with a thickness of 40 to 100 nm. The thus formed substrates are used as samples. For the method of forming the SiO₂, there can be used methods such as thermal oxidation in a dry atmosphere, thermal oxidation in a wet atmosphere, plasma CVD with TEOS (Tetra Ethyl Ortho Silicate) and O₂ used as source gases, thermal CVD with SiH₄ or SiH₂Cl₂ and N₂O used as source gases (so-called HTO), and thermal CVD with SiH₄ and O₂ used as source gases (so-called LTO). Here, the directions of crystal planes, resistivity, impurity concentrations, thicknesses and sizes of the SiC substrate samples, and film thicknesses of SiO₂ on the SiC substrate samples are those being exemplified, which are not necessarily limited thereto.

The heat treatment system used for forming the n-type SiC-MOS capacitor according to the invention by using the SiC substrate samples with the SiO₂ formed thereon has a structure in which a reaction tube of alumina passes through a cylinder-like resistance wire heating region surrounded with thermal insulation. Except that the reaction tube is made of alumina that allows temperature to be elevated up to 1800° C., the structure is similar to an oxidation furnace and a diffusion furnace used generally in a wafer process of a Si substrate. However, both ends of the reaction tube are sealed by flanges so that no air (particularly oxygen) is mixed in. The SiC substrate samples are mounted on an alumina boat and inserted into the reaction tube. For loading and unloading the boat, an alumina rod is used. The alumina rod is sealed by an O-ring provided at an opening at the end of the reaction tube so that no air is mixed in the reaction tube. While high purity Ar or another inert gas such as He at atmospheric pressure flows at 0.1 slm, for example, the temperature of the heating section at the center of the reaction tube is raised to a specified temperature (1740° C.). During this, the alumina boat with the SiC substrate samples mounted thereon is held while being preheated at a low temperature section downstream of the reaction tube (outside the heating section). The temperature at this time is on the order of 600° C. or less.

When the temperature of the heating section of the reaction tube becomes a specified temperature, the boat is inserted into the heating section and the Ar flow rate is immediately reduced to 0.01 slm. This is because when a temperature is high a high vapor pressure of SiO₂ causes all of the SiO₂ disposed upstream to be evaporated unless the Ar flow rate is reduced. After the temperature of the boat is raised to near a specified temperature, the boat is held for another 5 minutes at the temperature to bring the SiO₂ formed on the surface of the SiC substrate sample into a molten state. Then, with the Ar flow rate increased to 0.1 slm, the boat is immediately taken out to the low temperature section to be rapidly cooled. While the boat is being cooled, the set temperature of the heating section is reduced to 1140° C. When the temperature of the heating section is 1140° C., the boat is inserted into the heating section again and kept at 1140° C. for 15 minutes. In this case, no Ar flow rate control is necessary. Thereafter, the temperature is reduced to 600° C. at a rate of 5° C./min. When the temperature becomes 600° C., the boat is returned to the low temperature section downstream from the reaction tube to be naturally cooled until the temperature is low enough to allow the boat to be taken out. In this way, the SiC substrate samples heat treated according to the invention were formed. An Al film was deposited by sputtering on a SiO₂ on both the heat treated SiC substrate samples and SiC substrate samples that were not heat treated. The deposited Al films were then subjected to patterning by wet etching, by which a MOS capacitor was formed.

A comparison was made between SiC substrate samples subjected to heat treatment and comparison SiC substrate samples that were not subjected to heat treatment by carrying out the following analysis. The comparison was made to ascertain to what extent suboxides and carbon clusters due to carbon are removed and to what extent an interface state density is decreased at a SiO₂/SiC interface of the n-type SIC-MOS capacitor according to the invention by carrying out the heat treatment. The analysis was carried out by cross section observation under a TEM (Transmission Electron Microscope) and composition analysis with EELS (Electron Energy Loss Spectroscopy). As a result, the following was found.

In a SiC substrate sample for comparison with SiO₂ being formed by dry oxidation and wet oxidation but without being subjected to the heat treatment, there were observed regions with the presence of a mixture of Si atoms, C atoms and O atoms (suboxides) at the SiO₂/SiC interface and, on the SiO₂ side near the interface, there were observed deposits of carbon. In a SiC substrate sample for comparison with SiO₂ being formed by using TEOS, but without being subjected to the heat treatment, mixing of carbon was observed over the whole SiO₂, but no suboxides were found. Furthermore, in a SiC substrate sample for comparison with a SiO₂ being formed with an HTO and a LTO but without being subjected to the heat treatment, neither the mixing of C (carbon) nor suboxides were recognized. The above results were approximately the same as those generally well-known.

In the SiC substrate sample heat treated at 1740° C. according to the invention, neither the mixing of C (carbon) nor suboxides were recognized in any of the cases of using the methods of forming the SiO₂ regardless of the method of forming the SiO₂ itself. However, from the whole SiO₂, Na and transition metals were detected. They are regarded as metal impurities due to the use of the boat and reaction tube of alumina.

For comparison, an observation was made about a SiC substrate sample for comparison prepared by a method not included in the invention in which only heat treatment temperatures were changed from those in the heat treatment method according to the invention to be lower as 1290° C. and 1440° C. The result was rather similar to the result about the SiC substrate sample for comparison without being subjected to heat treatment. Namely, in the SiC substrate sample for comparison without being subjected to heat treatment in which the mixing of carbon and suboxides were observed, the mixing of carbon and suboxides were also observed even though the substrate sample was subjected to heat treatment at 1290° C. However, there was a difference in that the amounts of the mixing of carbon and suboxides were lower than those observed when the substrate sample was subjected to no heat treatment. Moreover, the substrate sample subjected to heat treatment at 1440° C. was different in that the mixing of carbon and suboxides was further lowered. However, partial deposition of SiO₂ microcrystals was also observed therein. This causes degradation in insulation strength. Therefore, the heat treatment carried out at the temperature is not included in the manufacturing method according to the invention.

Next, current to voltage characteristics were measured for a MOS capacitor formed by the manufacturing method according to the invention and a MOS capacitor formed by a manufacturing method that was not according to the invention. The MOS capacitor according to the invention, in which the heat treatment temperature was kept at 1740° C. to convert SiO₂ to a molten state before rapidly decreasing the temperature to rapidly cool the capacitor, had an insulation breakdown electric field strength of the order of 10 to 11 MV/cm. In a MOS capacitor in which the heat treatment temperature was kept at 1440° C., and SiO₂ was not converted to a molten state before the temperature was rapidly reduced to rapidly cool the capacitor, the insulation breakdown electric field strength was low, of the order of 5 to 8 MV/cm or less. This was due to deposition of microcrystals as explained before. In a MOS capacitor in which the heat treatment temperature was 1290° C., the insulation breakdown electric field strength was high, of the order of 8 to 10 MV/cm for the capacitor with a thermal oxide film formed by either dry oxidation or wet oxidation. For the capacitor with a deposited thermal oxide film formed by CVD, the insulation breakdown electric field strength was low, of the order of 3 to 7 MV/cm, regardless of deposition method. It is considered that a deposited oxide film has a tensional stress applied thereto in many cases by the SiC semiconductor substrate and the stress is insufficiently relaxed by a short time heat treatment in a non-oxidizing atmosphere making it impossible to obtain sufficient insulation strength.

Hysteresis due to mobile ions such as Na ions was observed regardless of heat treatment temperatures in the measurement of capacitance to voltage characteristics for the MOS capacitor subjected to the heat treatment according to Example 1 of the invention. In other respects, favorable characteristics were obtained with interface state densities obtained by Terman's method being below the minimum detectable value of Terman's method (taken as being on the order of 10¹² cm⁻³). It is considered that the interface state is neutralized by mobile ions such as Na ions.

As was explained in the foregoing, when heat treatment was carried out by using a reaction tube of alumina an unfavorable interface state may become favorable as a result of neutralization by metal impurities due to alumina. Thus, the favorable interface state is not necessarily caused by the effect of the heat treatment according to the invention. However, it can be said that high insulation strength evidently can be obtained by heating crystalline SiO₂ above the melting point thereof. Moreover, it is evident from the result of the above-explained analysis that carbon clusters and suboxides are removed in the SiO₂/SiC interface.

### Example 2

In Example 2, a manufacturing method of an n-type SiC-MOS capacitor according to the invention will be also explained. As in the Example 1, a modification in the conductivity type of a SiC substrate of course allows a p-type MOS capacitor and n-channel or p-channel MOSFET to be formed. In the following, explanations will be made with particular emphasis on the difference from Example 1.

In Example 2, a double tube of silica glass is used as a heat treatment system. The system has a structure in which cooling water is made to flow between the outer tube and the inner tube of the double tube. A SiC substrate sample with the SiO₂ according to the invention formed thereon and a dummy sample are mounted on a high purity graphite susceptor coated with polycrystalline SiC. The susceptor is set on a susceptor holder of silica glass with a thick felt of high purity porous graphite put between so that the susceptor does not make direct contact with the double tube of silica glass. The susceptor holder is set in the inner tube of the double tube. In the heat treatment system, there is a danger that the graphite susceptor heated at an elevated temperature causes a steam explosion if the susceptor makes direct contact with the double tube. This is because the susceptor is set on the susceptor holder of silica glass with the felt of graphite put between. The heating of the graphite susceptor is carried out by induction heating in high purity Ar gas or another inert gas such as He at atmospheric pressure by feeding a high frequency current to a coil wound on the double tube. Since the graphite susceptor has a sufficiently small heat capacity, rapid increase or decrease in temperature is possible with sufficiently large electric power. For a graphite susceptor being on the order of several centimeters both in width and in length and on the order of 1 cm in thickness, high frequency power of as much as 30 kW can elevate the temperature of the susceptor from room temperature to 1750° C. within 3 minutes by selecting an adequate frequency. Temperature reduction is also characterized in that the temperature reduction from 1750° C. to 1140° C. can be carried out within 3 minutes. The heat treatment profile is the same as that in Example 1 except that the heat treatment temperature is kept at the specified heat treatment temperature (1740° C.) for 5 minutes before being set at 1140° C. with the high frequency power reduced and kept as being reduced.

The SiO₂ in the SiC substrate sample subjected to the heat treatment by the method in Example 2 according to the invention was the same as that in Example 1 except that no Na or other metal impurities were detected in the composition analysis. There was no big difference in the current to voltage characteristics from those in Example 1.

The effect due to the high temperature heat treatment system according to Example 2 was definitely observed in the capacitance to voltage characteristics about the MOS capacitor subjected to the heat treatment by the method according to Example 2. There was observed little hysteresis due to mixing of Na as was observed in Example 1. Even though some hysteresis was observed, it was hysteresis due to electron trap (caused in the reverse direction to the direction of hysteresis due to mobile ions such as Na ions). An interface state density obtained by Hi-Lo method, the accuracy of which is higher than the accuracy in Terman's method, had a tendency to decrease as the heat treatment temperature was raised as 1290° C., 1440° C. and 1740° C. With a heat treatment temperature of 1740° C., the interface state density at 0.1 to 0.6 eV below the conduction band was 2×10¹¹ cm⁻²/eV or less and, particularly at 0.2 to 0.6 eV below the conduction band, was 1×10¹¹ cm⁻²/eV or less. These values are smaller by nearly two figures than the values of interface state densities reported for ordinary thermal oxide films.

The SiO₂ can be solidified from a liquefied state under conditions under which no Na or other metal impurities are incorporated into the SiO₂ by the method according to Example 2. Thus, the method according to Example 2 is excellent in that an interface state density can be decreased without relying on Na ions and the other mobile ions. Moreover, it was found that the insulation strength of the SiO₂ was also high.

### Example 3

In Example 3, the manufacturing method of an n-type SiC-MOS capacitor according to the invention will be explained. As in Examples 1 and 2, a p-type MOS capacitor and n-channel or p-channel MOSFET can be formed. For Example 3, explanations will be made with particular emphasis on the difference from Examples 1 and 2.

The heat treatment system used in Example 3 is a system in which a hollowed heat insulator of high purity graphite is placed in a reaction tube of silica glass of a SiC epitaxial growth system and a high purity graphite susceptor coated with polycrystalline SiC is set inside the insulator to be provided as the heat treatment system for the SiO₂ according to the invention. The graphite susceptor is horizontally grooved. Along the groove, a polycrystalline SiC substrate is placed. On the polycrystalline SiC substrate, a SiC substrate sample according to the invention and a dummy substrate are mounted (the dummy substrate is mounted upstream). The graphite susceptor is surrounded by a heat insulator with a large heat capacity, so that the temperature thereof is not decreased easily. Only the polycrystalline SiC substrate is pulled out by means of tongs, for example. The polycrystalline SiC substrate, having considerably smaller heat capacity compared with that of the graphite susceptor, is rapidly cooled. The heat treatment profile in Example 3 is the same as that in Example 1.

The composition, current to voltage characteristics and capacitance to voltage characteristics of the SiC-MOS capacitor subjected to the heat treatment in a non-oxidizing atmosphere such as that with high purity Ar or another inert gas such as He at atmospheric pressure with the profile being the same as that in Example 1 were approximately equal to those in Example 2.

In the heat treatment in Example 3, the SiO₂ can be solidified from a liquefied state under conditions under which no Na or other metal impurities are incorporated into SiO₂. Thus, the interface state density can be decreased without relying on Na ions and the other mobile ions. Moreover, the insulation strength of the SiO₂ is also high. Furthermore, the heat treatment system is very practical, because it is capable of simultaneously processing a number of samples without danger of steam explosion as compared with the system in Example 2.

### Example 4

In Example 4, the manufacturing method of an n-type SiC-MOS capacitor according to the invention will be explained. As in Examples 1 to 3, a p-type MOS capacitor and n-channel or p-channel MOSFET can be formed. In Example 4, explanations will be made with particular emphasis on the difference from Examples 1 to 3. In each of the methods in the previous Examples 1 to 3, the SiC substrate sample is subjected to heat treatment with the heat treatment profile of raising a temperature to liquefy the SiO₂ and then rapidly decreasing the temperature to rapidly cool the SiO₂. In the method in Example 4, there is a significant difference from Examples 1 to 3 in that the SiO₂ is heated up to a temperature lower than the temperature that liquefies SiO₂ and then rapidly cooled. This will be explained in the following.

In Example 4, a heat treatment system similar to that in Example 3 is used. The difference from the system in Example 3 is that SiH₄ flows together with Ar as non-oxidizing atmospheric gases at heat treatment. An excessive SiH₄ flow rate causes either deposition of polycrystalline Si or adhesion of fluid Si depending on temperature (referred together to as adhesion of Si). This, however, is not a fatal problem. This is because adhered Si can be selectively removed by using intermediate pressure plasma producing fluorine radials without causing ion irradiation onto a formed SiO₂ and, when the formed SiO₂ is used as a gate insulator film for a device such as a MOSFET, can also be used as gate polysilicon. As in Example 3, the dummy substrate is mounted upstream from the sample.

In Example 4, by using a heat treatment system similar to that used in Example 3, the temperature of the SiC substrate sample is raised up to 1440° C. while making Ar, for example, flow at a flow rate of 0.1 slm and, along with this, making SiH₄ flow at a flow rate of 0.1 to 1.0 slm. The SiC substrate sample, after being kept at 1440° C. for a specified time, is once pulled out to a lower temperature section and is rapidly cooled. Thereafter, the SiC substrate sample is inserted again into the heating section the temperature of which is reset at 1140° C. for gradually cooling. The treatment of the SiC substrate sample after being kept for 15 minutes at the gradual cooling temperature of 1140° C. is similar to that in Example 1.

The upper limit of the heat treatment temperature in Example 4 is 1450° C. This is because a heat treatment temperature exceeding 1450° C. unfavorably causes the vapor pressure of SiO₂ to be excessively high. The lower limit of the heat treatment temperature is 1250° C. This is because a heat treatment temperature less than 1250° C. causes the diffusion velocity of Si in the SiO₂ to be too small, which provides no practicality in the aspect of efficiency.

In Example 4, even in the SiC substrate sample heat treated at 1440° C., neither mixing of C (carbon), nor the presence of suboxides, nor further generation of SiO₂ microcrystal as was explained in Example 1 can be recognized regardless of the methods of forming the SiO₂. Moreover, a comparison of the interface state densities of the SiC substrate samples with those obtained at the same treatment temperature in Example 3 showed that each of the SiC sample substrates subjected to the heat treatment in Example 4, including the SiC substrate sample heat treated with the temperature 1440° C. changed to 1290° C., had a smaller interface state density. In other words, the method according to Example 4 is characterized in that an interface state density can be decreased without carrying out heat treatment at an elevated temperature such as 1740° C. as in the case of Example 3.

In Example 4, silane gas was used as a silicon producing gas. However, other hydrogenated silicon gases can be used. For the other silicon producing gases, when the gases cause no oxidation of SiC, gases such as evaporated gas of Si and Si oxide gases that causes no oxidation of SiC can be used.

It is considered that according to Example 4, diffusion of Si atoms in SiO₂ causes no production of such SiO₂ microcrystals as to increase the interface state density and the diffused Si atoms are removed by reacting with carbon impurities and suboxides to result in a decrease in interface state density. Moreover, the method according to Example 4, compared with the methods according to Examples 1 to 3, has the advantage of decreasing an interface state density without using such an abnormally high temperature as 1740° C.

### Example 5

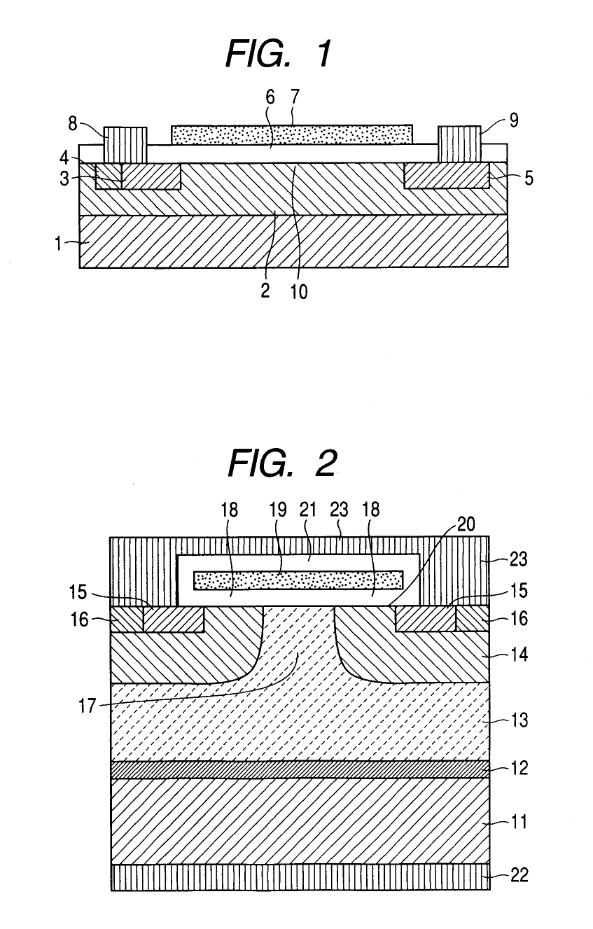

In Example 5, an n-channel lateral MOSFET, a cross sectional view of the principal part of which is shown in FIG. 1, will be explained in the following. On SiC substrate 1, p-type body region 2 is formed by SiC epitaxial growth. In a part of the surface of p-type body region 2 with which source electrode 8 is in ohmic contact, n⁺-type source contact region 3 and p⁺-type body contact region 4 are provided adjacent to each other. N⁺-type drain contact region 5 is provided in the surface layer of p-type body region 2, at a position opposite to n⁺-type source contact region 3, with MOS channel 10 placed between. Drain electrode 9 is in ohmic contact with n⁺-type drain contact region 5. The conductance between n⁺-type source contact region 3 and n⁺-type drain contact region 5 is controlled by MOS channel 10. On the surface in a part where MOS channel 10 is to be formed on the surface of p-type body region 2, gate electrode 7 is provided with gate oxide film 6 provided between.

The manufacturing method of the n-channel lateral MOSFET will be explained. A 4H—SiC (0001)_{Si} and (000 1̅)_{C} plane 8° off substrate and a 4H—SiC (11 2̅0) plane just plane substrate are prepared. The conductivity type and the resistivity of each of the substrates can be selected as required. On each of the substrates, a p-type SiC layer with an acceptor density of 2×10¹⁷ cm⁻³ is formed to a thickness of 2 μm by epitaxial growth. Next, as an appropriate mask material, a deposited SiO₂ film is formed on the p-type SiC layer with a thickness of 1.5 μm, for example, and is patterned. Then, ion implantation with phosphorus ions is carried out into a region to a depth of 0.2 μm from the surface of the p-type SiC layer to form n⁺-type source contact region 3 and n⁺-type drain contact region 5, with the SiC substrate sample heated at 800° C., for example, so that the implanted ions form a box profile with an averaged density of 1×10²¹ cm⁻³. Similarly, an appropriate mask material is formed on the p-type SiC layer to be patterned. Then, ion implantation with aluminum ions is carried out into a region to a depth of 0.2 μm from the surface of the p-type SiC layer to form p⁺-type body contact region 4, with the SiC substrate sample heated at 500° C., so that the implanted ions form a box profile with an averaged density of 1×10²¹ cm⁻³. After the mask materials are removed, annealing to activate the implanted ions is carried out in an Ar atmosphere at 1800° C. to form n⁺-type source contact region 3, p⁺-type body contact region 4 and n⁺-type drain contact region 5. A section not subjected to ion implantation becomes p-type body region 2 of the p-type epitaxial layer. At this time, the surface of p-type body region 2 is preferably capped with carbon to prevent the surface from becoming rough.

Next, gate oxide film 6 is formed by using any one of the methods of forming SiO₂ described in Examples 2 to 4 and the heat treatment method according to the invention. The thickness of gate oxide film 6 was made uniform to on the order of 80 nm. Subsequently, polysilicon doped with highly concentrated phosphorus is deposited on gate oxide film 6 (phosphorus may be driven in after undoped silicon is deposited) and then etched back, by which gate electrode 7 is formed. In forming gate oxide film 6 by the method described in Example 4, when polysilicon is deposited from the beginning, the polysilicon may be used to form gate electrode 7. The specified sections of gate oxide film 6 are etched to provide opening sections, in which Ni is deposited by sputtering. The deposited Ni is then patterned to provide source electrode 8 and drain electrode 9, which are thereafter heated at 1000° C. in an Ar atmosphere to obtain ohmic contact. Note that the above-described values such as those of directions of crystal planes (including the off angle), the doping densities, film thicknesses and the implantation depths are only exemplified ones.

The value of channel mobility of the formed n-channel lateral MOSFET shown in FIG. 1 was obtained as 200 to 300 cm²V/s in the MOSFET in which the SiO₂ was heat treated at 1740° C. The value of channel mobility obtained when a gate oxide film is formed by an ordinary method was, depending on the direction of crystal plane, on the order of 1 to 140 cm²/Vs (except a gate oxide film containing metal impurities such as Na). Therefore, it is known that high channel mobility can be obtained in the n-channel lateral MOSFET according to Example 5. Carbon impurities and suboxides as causes of forming interface states are removed in the MOSFET in Example 5 to therefore make it possible to obtain high channel mobility. In Example 5, the MOSFET was provided as a planar gate lateral MOSFET. However, it may be provided as a trench gate lateral MOSFET.

### Example 6

Example 6 relates to an n-channel vertical MOSFET, a cross sectional view of the principal part of which is shown in FIG. 2. N⁺-type field stopping layer 12 with a high impurity concentration and n-type drift layer 13 with a low impurity concentration are formed in order on SiC substrate 11 which has a plane of n-type 4H—SiC with high impurity concentration taken as a principal surface. P-type body region 14 is formed in a part of n-type drift layer 13. Thus, n-type drift region 13 appears on the semiconductor surface only in the part of JFET region 17 of the principal surface. N⁺-type source contact region 15 with a high impurity concentration and p⁺-type body contact region 16 with a high impurity concentration are provided adjacent to each other in a part of p-type body region 14, with which a source electrode 23 is in ohmic contact. Drain electrode 22 is in ohmic contact with the opposite side of the principal surface of SiC substrate 11. The conductance between n⁺-type source contact region 15 and drain electrode 22 is controlled by MOS channel 20. On p-type body region 14, gate electrode 19 is provided with gate oxide film 18 held between on the surface in a part where at least MOS channel 20 is to be formed. Interlayer insulation film 21 is positioned over gate electrode 19. Actually, for the realization of a high breakdown voltage, a well-known electric field limiting structure (not shown) is provided at an end of the device. However, the electric field limiting structure is not directly related to the invention and the detailed explanation of the structure will be therefore omitted.

The manufacturing method of the n-channel vertical MOSFET will be explained. A 4H—SiC (0001)_{Si} and (000 1̅)_{C} plane 8° off substrate is prepared as SiC substrate 11. N⁺-type field stopping layer 12 (with a donor density of 0.5×10¹⁷ to 10×10¹⁷ cm⁻³) is deposited to approximately 2 μm thick and n-type drift layer 13 (with a donor density of approximately 1.3×10¹⁶ cm⁻³) is deposited to approximately 8.9 μm thick in this order on SiC substrate 11. Next, the surface of n-type drift layer 13 is covered with an appropriate mask material, which is then appropriately patterned. Then, ion implantation with aluminum ions is carried out into a region to a depth of 1.9 μm, for example, from the surface of n-type drift layer 13 together with the deposited layers 12 and 13 and the mask material, with SiC substrate 11 heated at 500° C., for example, to form p-type body region 14, so that the implanted ions form a box profile with an averaged density of 2×10¹⁷ cm⁻³. When the densities of aluminum are equal over the semiconductor surface, the density of aluminum may be given so as to increase in the depth direction instead of being given to form a box profile.

Following this, the surface of n-type drift layer 13 is covered with an appropriate mask material, which is then appropriately patterned. Then, ion implantation with phosphorus ions is carried out into a region to a depth of 0.4 μm from the surface of n-type drift layer 13 together with layers 12 and 13 and the mask material to form n⁺-type source contact region 15, with SiC substrate 11 heated at 800° C., for example, so that the implanted ions form a box profile with an averaged density of 1×10²¹ cm⁻³. Similarly, ion implantation with aluminum ions is carried out with the use of an appropriately patterned mask material into a region to a depth of 0.4 μm from the surface of n-type drift layer 13 together with the layers 12 and 13 and the mask material, with SiC substrate 11 heated at 500° C., for example, to form p⁺-type body contact region 16, so that the implanted ions form a box profile with an averaged density of 1×10²¹ cm⁻³. After the mask materials are removed, annealing to activate the implanted ions is carried out in an Ar atmosphere at 1800° C. to form p-type body region 14, n⁺-type source contact region 15, and p⁺-type body contact region 16. At this time, the surface of n-type drift layer 13 is preferably capped with carbon to prevent the surface from becoming rough.

Next, the specified sections of gate oxide film 18 are etched to provide opening sections in which Ni is deposited by sputtering. The deposited Ni is then patterned to be provided as source electrode 23. Also on the principal surface on the opposite side of SiC substrate 11, with an oxide film being removed, Ni is deposited by sputtering as drain electrode 22. Electrodes 22 and 23 are thereafter heated at 1000° C. in an Ar atmosphere to obtain ohmic contact. Note that the above-described values such as those of directions of crystal planes (including the off angle), the doping densities, film thicknesses and the implantation depths are only exemplified ones. The design breakdown voltage of the MOSFET in Example 6 is 1.2 kV.

The on-resistance of the formed vertical MOSFET was 8.8 to 9.0 mΩcm². While, the resistance obtained from a TEG (Test Element Group) for evaluation, formed together with the MOSFET in the same wafer at the same time, was on the order of 8.5 mΩcm² about the sections other than MOS channel 20. Therefore, the value of the channel resistance of the MOSFET becomes 0.3 to 0.5 mΩcm² which is calculated by subtracting the value 8.5 mΩcm² from the on-resistance of the MOSFET of 8.8 to 9.0 mΩcm². Thus, it is known that the ratio of the channel resistance component to the whole on-resistance can be reduced down to on the order of 0.5%.

In a previous vertical SiC MOSFET, the channel resistance component occupied 30 to 50% of the on-resistance. Therefore, in the MOSFET in Example 6 according to the invention, the channel resistance ratio can be largely reduced.

As was explained above, according to Example 6, carbon impurities and suboxides that cause interface states are removed, by which channel mobility is enhanced, channel resistance is reduced and, as a whole, on-resistance can be decreased.

### Example 7

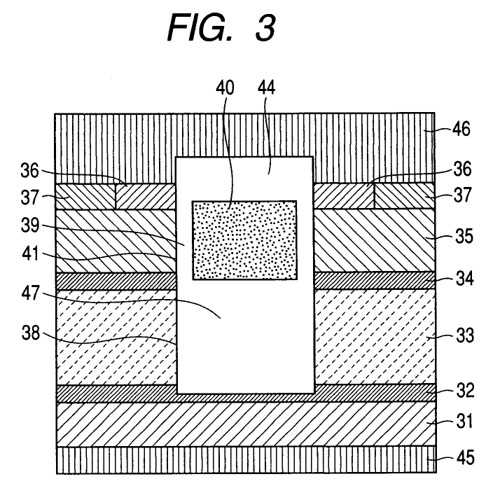

In Example 7, an n-channel trench MOSFET, a cross sectional view of the principal part of which is shown in FIG. 3, will be explained. N⁺-type field stopping layer 32 with a high impurity concentration, n-type drift layer 33 with a low impurity concentration, n-type current spreading layer 34, p-type body region 35, n⁺-type source contact region 36 with a high impurity concentration and p⁺-type body contact region 37 are formed in order on SiC substrate 31 with a plane of n-type SiC with high impurity concentration taken as a principal surface. Trench 38, which penetrates p-type body region 35, n-type current spreading layer 34 and n-type drift layer 33 to reach n⁺-type field stopping layer 32 is formed from the surface of n⁺-type source contact region 36. Inside trench 38, gate electrode 40 is provided with gate oxide film 39 held between. Gate electrode 40 is positioned in a section ranging from a part of n⁺-type source contact region 36 adjacent to p-type body region 35 to a part of n-type current spreading layer 34 adjacent to p-type body region 35 over p-type body region 35. The section of trench 38 below gate electrode 40 is filled with embedded insulator 47, the main component of which is SiO₂. Of the surface of the trench 38, with the section above the gate electrode 40 and a part of the section formed with the n⁺-type source contact region 36, an interlayer insulator film 44 is formed so as to be in contact.

Source electrode 46 is provided on the surface of n⁺-type source contact region 36 in the direction along the surface of the substrate, so as to make ohmic contact with the surface. Source electrode 46, while covering the interlayer insulator film 44, is in contact with n⁺-type source contact region 36 in the adjacent cell. A part of source electrode 46 is in contact with p⁺-type body contact region 37 with a high impurity concentration, which region enters p-type body region 35. A drain electrode is in ohmic contact with the bottom surface of SiC substrate 31. Furthermore, in an actual device, an electric field limiting structure is provided at an end of the device (not shown). The explanation of this is not required for understanding the invention and will be omitted. About the manufacturing method of the vertical trench MOSFET previously shown in FIG. 3, detailed explanation will be given in the following.

N-type 4H—SiC substrate 31 with a (0001)_{Si} 8° off plane taken as a principal surface thereof or n-type 4H—SiC substrate 31 with a (000 1̅)_{C} 8° off plane (hereinafter “substrate 31”) taken as a principal surface thereof is prepared. The effective donor density of substrate 31 is on the order of 1×10¹⁸ cm⁻³. The thickness of substrate 31 is around 400 μm.

N⁺-type field stopping layer 32, n-type drift layer 33, n-type current spreading layer 34, p-type body region 35 and an n⁺-type source contact layer are deposited in order by epitaxial growth on substrate 31. After the epitaxial growth process, SiO₂ with a thickness of approximately 2 μm is deposited on the surface on the source contact layer side by plasma CVD with TEOS and O₂ used as source gases. The deposited SiO₂ is formed as a SiO₂ mask for ion implantation by photolithography process and plasma etching. Thermal oxidation is then carried out in a wet atmosphere at 1000° C. to 1200° C. for a specified time, for example 30 minutes, to form a screen oxide film with a thickness of approximately 10 nm.

Ion implantation with aluminum ions is carried out to a depth of 0.4 μm from the undersurface of the screen oxide film, with the substrate sample heated at 500° C., so that the implanted ions form a box profile with an averaged density of 1.5×10²¹ cm⁻³. Then a photoresist is applied again, which is heated at 800° C. in an Ar flow to carbonize and provide a carbon cap. In this state, by keeping the substrate sample at 1800° C. for 5 minutes in an Ar flow, aluminum ions introduced by ion implantation are activated. The substrate sample is kept at 800° C. in an O₂ flow to remove the carbon cap.

By the processes up to this point, p⁺-type body contact region 37 is formed in a part of the source contact layer. The remaining part of the source contact layer becomes n⁺-type source contact region 36.

After SiO₂ with a thickness of approximately 3.7 μm is deposited on p⁺-type body contact region 37 side surface of the substrate sample by plasma CVD, a mask pattern of the SiO₂ for forming the trench is formed by a photolithography process and plasma etching. By ICP (Inductively Coupled Plasma) etching (RIE: Reactive Ion Etching) with SF₆ and O₂ taken as reactive gases, trench 38 is formed which reaches n⁺-type field stopping layer 32. A maximum of the ratio of the etching rate of SiC to that of SiO₂ (selective ratio) is on the order of 2.3. Therefore, with SiO₂ with a thickness of approximately 3.7 μm used as a mask, trench 8 reaching n⁺-type field stopping layer 32 at a depth of a little less than 8 μm can easily be formed. By forming a sacrifice oxide film with a thickness of approximately 40 nm and subsequently removing it, the inside surface of trench 38 is cleaned.

Trench 38 is filled with a SiO₂ or an insulator including SiO₂ as the main component. After trench 38 is filled with the SiO₂, the SiO₂ is heated to convert it into a molten state and make it dense. Therefore, in the step of forming the SiO₂, it is necessary only that the whole volume of SiO₂ is larger than the whole volume of trench 38. Thus, it is not necessary for the SiO₂ to be uniformly and densely deposited in trench 38, so that a simplified deposition method can be employed.

Next, the deposited SiO₂ is heated up to 1740° C. by the heat treatment method described in Example 2 or 3. At this time, the SiO₂, is liquefied and flows into trench 38. When the temperature is lowered, the SiO₂ solidifies to uniformly fill trench 38. Subsequent to this, polishing is carried out for planarization with the principal surface of the SiC used as an etching termination surface. The use of silica as abrasives causes the SiO₂ to be shaved, but SiC, being far harder than silica, is barely shaved. However, when the temperature of SiC is raised by polishing, the surface of SiC is oxidized to allow the surface to be shaved. Therefore, care must be taken so as not to excessively raise the temperature.

When the SiO₂ remaining on the SiC surface is sufficiently flat with the thickness thereof known by a detection method of some kind, the SiO₂ may be polished by RIE (Reactive Ion Etching) with an etching gas such as CHF₃ used without carrying out polishing. Finally, the SiO₂ is etched back to a specified depth, by which burial of insulator 47 in trench 38 is completed. For the etching back, plasma etching may be carried out with CHF₃ used as a reactive gas. Because of the presence of some conditions under which the selectivity of SiO₂ to SiC becomes 40 or more, the SiC can be safely made exposed on the principal surface. However, in some cases, CHF₃ forms a polymerized film on the surface of a SiC. In this case, the polymerized film must be removed later by O₂ plasma.

By plasma CVD with TEOS and O₂ used as source gases, a SiO₂ is formed on the sidewall of trench 38 with a thickness of approximately 10 nm. By carrying out high temperature heat treatment at 1300° C. for 1 hour with 10% N₂O diluted with N₂, the SiO₂ on the sidewall surface is provided as gate oxide film 39.

The high temperature heat treatment at 1300° C. is preferable because the treatment brings the advantages of enhanced breakdown voltages and improved interface characteristics to not only the gate insulator film but also to the SiO₂ buried in the trench, namely the buried insulator and a SiO₂ left on the principal surface before the gate oxide film is deposited.

The processes after this are almost the same as those of forming a Si trench MOSFET except that the contact with SiC is made with Ni and high temperature annealing of the order of 1000° C. is carried out. Following the gate oxide film forming process, the trench is filled by depositing polysilicon including phosphorus with a high concentration. The polysilicon is then etched back to a specified depth to be formed as gate electrode 40. Thereafter, interlayer insulator film 44 is deposited, a contact hole is formed, and Ni is deposited on both of interlayer insulator film 44 and the bottom surface of substrate 31, by which source electrode 46 and drain electrode 45 are formed. By forming Al films on a gate pad and source electrode 46, the trench MOSFET is made completed.

The thus formed trench MOSFET can enhance averaged breakdown voltage due to a reduction in negative fixed charges, apparently possessed by insulator 47 buried in trench 38, which reduction is caused by a decrease in the interface state density at the SiO₂/SiC in the sidewall surface of trench 38.

As described above, according to Example 7, the decrease in the interface state density at the SiO₂/SiC in the sidewall surface of trench 38 enhances breakdown voltage. Moreover, the process of burying insulator 47 in trench 38 is simplified.

While the present invention has been particularly shown and described with reference to preferred embodiments thereof, it will be understood by those skilled in the art that the foregoing and other changes in form and details can be made therein without departing from the spirit and scope of the present invention.

What is claimed is:

1. A method of manufacturing a silicon carbide semiconductor device including a process of forming an oxide layer which includes silicon oxide as a main component on a silicon carbide semiconductor substrate, comprising:
forming a layer of silicon oxide on a surface of a silicon carbide semiconductor substrate;
heating the layer of silicon oxide in a non-oxidizing atmosphere to a temperature which brings the silicon oxide into a liquefied state containing no crystals; and then
rapidly cooling the layer of silicon oxide to a temperature equal to or less than a slow cooling temperature to form an oxide layer including silicon oxide as a main component.

2. The method of manufacturing a silicon carbide semiconductor device as claimed in claim 1, wherein the silicon oxide is heated in the non-oxidizing atmosphere to a temperature of 1730° C. or more and wherein the slow cooling temperature is a temperature at which no crystal of SiO₂ is substantially produced in SiO₂ in an amorphous state.

3. The method of manufacturing a silicon carbide semiconductor device as claimed in claim 2, wherein the slow cooling temperature is 1140° C.

4. A method of manufacturing a silicon carbide semiconductor device including a process of forming an oxide layer which includes silicon oxide as a main component on a silicon carbide semiconductor substrate, comprising:
forming a layer of silicon oxide on a surface of a silicon carbide semiconductor substrate;
heating the layer of silicon oxide to a temperature between 1250° C. and 1450° C. under a supply of gaseous silicon in a non-oxidizing atmosphere; and
rapidly cooling the layer of silicon oxide down to a temperature equal to or less than 1140° C. to form an oxide layer including silicon oxide as a main component.

5. The method of manufacturing a silicon carbide semiconductor device as claimed in claim 4, wherein the gaseous silicon is produced from hydrogenated silicon.

6. The method of manufacturing a silicon carbide semiconductor device as claimed in claim 5, wherein the hydrogenated silicon is silane.

7. A silicon carbide semiconductor device having a structure provided with a metal electrode on a surface of a silicon carbide semiconductor substrate with an oxide layer including silicon oxide as a main component produced according to claim 1.

8. The silicon carbide semiconductor device as claimed in claim 7, wherein all metal electrodes and MOS gate structure of a MOSFET are provided on one of principal surfaces of the silicon carbide semiconductor substrate.

9. The silicon carbide semiconductor device as claimed in claim 7, wherein the metal electrode are provided on each of the principal surfaces so that a current path is provided from the one of the principal surfaces to the other principal surface of the silicon carbide semiconductor substrate and the MOS gate structure is provided on either one of the principal surfaces.

10. The silicon carbide semiconductor device as claimed in claim 8, wherein the MOS gate structure is a trench MOS gate structure.

11. The silicon carbide semiconductor device as claimed in claim 9, wherein the MOS gate structure is a trench MOS gate structure.

12. A silicon carbide semiconductor device wherein a trench MOS gate structure is provided on a principal surface of a silicon carbide semiconductor substrate, and an oxide layer with silicon oxide as a main component is formed in a trench of the trench MOS gate structure, wherein the oxide layer is produced as claimed in claim 1.
